(19) United States
(12) Patent Application Publication
(10) Pub. No.: US 2026/0305225 A1
(43) Pub. Date: Oct. 1, 2026

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Yi-Xuan LIU, Hsinchu City (TW); Yung-Tsun LIU, Taipei City (TW); Kuang-Wei CHENG, Hsinchu City (TW)

(21) Appl. No.: 19/089,740

(22) Filed: Mar. 25, 2025

(51) Int. Cl. H01L 21/67

(52) U.S. Cl. CPC H10P 72/0421

(57) ABSTRACT

A diffusion plate, for use in an etch tool, may be configured to promote a uniform flow rate of a gas-based etchant across a semiconductor substrate in a etch operation. The diffusion plate may have a curved three-dimensional shape, such as a bowl shape, a dome shape, and/or another type of hollow shell shape. The upward curvature of the diffusion plate may equalize the gate flow rate of a gas-based etchant across a semiconductor substrate by restricting the flow of the gas-based etchant as the gas-based etchant flows toward the perimeter of the diffusion plate. Additionally and/or alternatively, the diffusion plate includes a plurality of holes through which the gas-based etchant flows. The holes may be arranged in regions of the diffusion plate having different sized holes to equalize the gate flow rate of the gas-based etchant across a semiconductor substrate.

### BACKGROUND

An etch tool is a semiconductor processing tool that is capable of etching various types of materials of a semiconductor substrate. Examples of etch tool types include a plasma-based etch tool that uses a plasma-assisted etch technique (e.g., a plasma sputtering technique or another type of technique), a gas-based etch tool that uses a gas-based etchant, and a wet etch tool that uses a wet etchant, among other examples. An etch tool may be used to perform isotropic etching (e.g., omnidirectional etching), anisotropic etching (e.g., directional etching), and/or a combination thereof.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor processing tool described herein.

FIGS. 2A and 2B are diagrams of an example implementation of a diffusion plate described herein for use in the semiconductor processing tool of FIG. 1.

FIGS. 3A and 3B are diagrams of an example implementation of an etch operation described herein.

FIG. 4 is a diagram of an example implementation of an etch operation described herein.

FIG. 5 is a diagram of an example implementation of an etch operation described herein.

FIG. 6 is a diagram of an example implementation of a diffusion plate described herein for use in the semiconductor processing tool of FIG. 1.

FIG. 7 is a diagram of an example implementation of a diffusion plate described herein for use in the semiconductor processing tool of FIG. 1.

FIG. 8 is a diagram of an example implementation of a diffusion plate described herein for use in the semiconductor processing tool of FIG. 1.

FIG. 9 is a diagram of example components of one or more devices of FIG. 1 described herein.

FIG. 10 is a flowchart of an example process associated with performing an etch operation.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a gas-based etch operation, a gas-based etch tool may be used to provide a flow of a gas-based etchant, such as a fluorine-containing gas and/or a chlorine-containing gas, into a processing chamber of the gas-based etch tool. The gas-based etchant may react with one or more layers and/or structures on a semiconductor substrate in the processing chamber to remove material from the semiconductor substrate.

One parameter that is controlled for in a gas-based etch operation is etch uniformity across a semiconductor substrate. The etch uniformity may be defined as a percentage of variation in the etch rate of the gas-based etchant across the surface of the semiconductor substrate. A high etch uniformity may indicate that the difference in etch rate between the center of the semiconductor substrate and the outer perimeter of the semiconductor substrate is low, meaning that material is removed across the semiconductor substrate in a highly uniform manner. Conversely, a low etch uniformity may indicate that the difference in etch rate between the center of the semiconductor substrate and the outer perimeter of the semiconductor substrate is high, meaning that material is removed at a faster rate in some areas of the semiconductor substrate than other areas of the semiconductor substrate.

A low etch uniformity in a gas-based etch operation for a semiconductor substrate can lead to the formation of defects in one or more semiconductor devices formed on the semiconductor substrate. As an example, if semiconductor devices located at a perimeter of the semiconductor substrate are etched at a faster rate in the gas-based etch operation than semiconductor devices located at a center of the semiconductor substrate, over-etching may occur in the semiconductor devices located at the perimeter and/or under-etching may occur in the semiconductor devices located at the center.

The over-etching may result in damage to one or more layers and/or structures of the semiconductor devices located at the perimeter, which may reduce the yield of semiconductor devices located at the perimeter. The under-etching may result in incomplete removal of material from one or more layers and/or structures of the semiconductor devices located at the center, and this can cause defects to form in subsequent processes for these semiconductor devices. For example, under-etching of a dielectric layer when forming contact recesses for source/drain contacts may result in open circuit formation, because the source/drain contacts do not make electrical connections with the underlying source/drain regions (e.g., due to dielectric material of the dielectric layer remaining over the source/drain regions).

In some implementations described herein, an etch tool (e.g., a gas-based etch tool) may be fitted with a diffusion plate that is included in the etch tool to promote a uniform flow rate of a gas-based etchant across a semiconductor substrate in a gas-based etch operation. The diffusion plate may have a curved three-dimensional shape, such as a bowl shape, a dome shape, and/or another type of hollow shell shape. The body of the diffusion plate may have a resulting concave cross-sectional profile, where the body of the diffusion plate curves upward from the center of the body to the perimeter of the body toward an upper lid of a processing chamber of the etch tool. The upward curvature of the diffusion plate may equalize the gas flow rate of the gas-based etchant across a semiconductor substrate by restricting the flow of the gas-based etchant as the gas-based etchant flows toward the perimeter of the diffusion plate.

Additionally and/or alternatively, the diffusion plate includes a plurality of holes through which the gas-based etchant flows, and different regions of the diffusion plate may have subsets of holes that have different sizes. The hole sizes in the different regions are configured to equalize the gate flow rate of the gas-based etchant across a semiconductor substrate by restricting the flow of the gas-based etchant in regions of the diffusion plate, while promoting the flow of the gas-based etchant in other regions of the diffusion plate.

In this way, the high uniformity in the flow rate of the gas-based etchant enables a high uniformity in the etch rate across the semiconductor substrate to be achieved. The high uniformity in the etch rate across the semiconductor substrate reduces the likelihood and/or the rate of defect formation in semiconductor devices formed on the semiconductor substrate by reducing over-etching and under-etching across the semiconductor substrate.

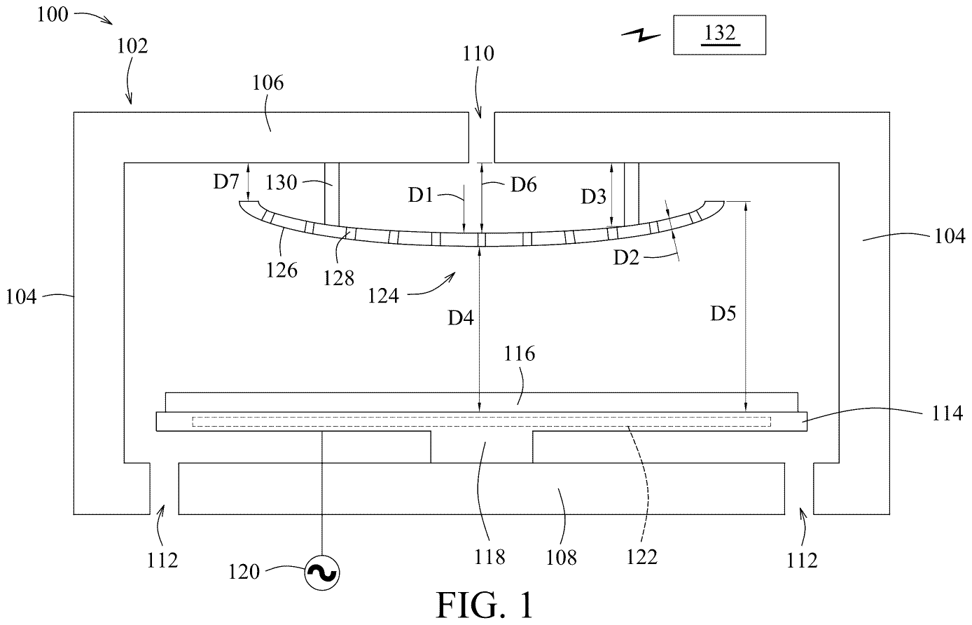

FIG. 1 is a diagram of an example semiconductor processing tool 100 described herein. The semiconductor processing tool 100 may be an etch tool, such as a gas-based etch tool, that is used to etch layers and/or structures on semiconductor substrates in semiconductor manufacturing.

As shown in FIG. 1, the semiconductor processing tool 100 includes a processing chamber 102. The processing chamber 102 may include sidewalls 104, an upper cover 106, and a chamber floor 108 that define an inner volume in which semiconductor substrates are processed. In some implementations, the processing chamber 102 further includes a door or another type of access point through which semiconductor substrates are provided into, and removed from, the processing chamber 102. In some implementations, the upper cover 106 is removable from the sidewalls 104 to provide access into the processing chamber 102 for maintenance, troubleshooting, and/or cleaning.

At the top of the processing chamber 102, a gas inlet 110 may be located in the upper cover 106. The gas inlet 110 may be an opening through the upper cover 106 through which a gas-based etchant flows into the processing chamber 102. The gas inlet 110 may be coupled to a gas delivery system (not shown) of the semiconductor processing tool 100 that is configured to provide the gas-based etchant to the gas inlet 110.

At the bottom of the processing chamber 102, one or more vent ports 112 may be located in the chamber floor 108. The vent port(s) 112 include openings through the chamber floor 108 through which gas-based etchant and etchant byproducts may flow out of the processing chamber 102. In some implementations, the vent port(s) 112 are coupled to vacuum pumps (not shown) that generate a negative pressure in the processing chamber 102 to facilitate the flow of gas-based etchant downward from the gas inlet 110 toward the vent port(s) 112.

The vent port(s) 112 may be located below a chuck 114 that is located in the processing chamber 102. The chuck 114 may include a platform that is sized and/or shaped to accommodate a semiconductor substrate 116 on the chuck 114. For example, the semiconductor substrate 116 may be a round semiconductor wafer, and the chuck 114 may be a round platform that conforms to the shape of the semiconductor wafer. The chuck 114 may be an electrostatic chuck that is configured to secure the semiconductor substrate 116 by an electrostatic clamping force, a vacuum chuck that is configured to secure the semiconductor substrate 116 by a vacuum clamping force, and/or another type of chuck that is configured to secure the semiconductor substrate 116 by another type of clamping force.

The chuck 114 may be supported in the processing chamber 102 by a pedestal 118. In some implementations, the pedestal 118 is configured to rotate the chuck 114 so as to rotate the semiconductor substrate 116 on the chuck 114 during an etch operation. The chuck 114 may be coupled to a radio frequency (RF) source 120, which may be used to apply an electrical bias to the chuck 114 for controlling the flow of gas-based etchant in the processing chamber 102. The chuck 114 may also include a heater element 122 that may be used to heat the semiconductor substrate 116 so as to maintain the temperature of the semiconductor substrate 116 at a consistent temperature and/or within a temperature range during an etch operation.

As further shown in FIG. 1, a diffusion plate 124 may be positioned within the processing chamber 102. The diffusion plate 124 may be located vertically between the chuck 114 and the gas inlet 110 in the upper cover 106 of the processing chamber 102 so that gas-based etchant passes through the diffusion plate 124 toward the semiconductor substrate 116 on the chuck 114. The diffusion plate 124 may be included in the processing chamber 102 to control the flow of gas-based etchant in an etch operation, and particularly to achieve a high uniformity of the flow rate of the gas-based etchant (and thus, a high uniformity in the etch rate) across the semiconductor substrate 116 in the etch operation.

The diffusion plate 124 includes a body 126 and a plurality of holes (or perforations) 128 through the body 126. The holes 128 may be distributed across the body 126 and may extend from one surface (e.g., a top surface) to another surface (e.g., a bottom surface) of the body 126. The gate-based etchant may be provided into the processing chamber 102 through the gas inlet 110, and may flow through the holes 128 in the body 126 of the diffusion plate 124. This may collimate and reduce turbulence in the flow pattern of the gas-based etchant in the processing chamber 102. In some implementations, the gas-based etchant flowing through the holes 128 in the body 126 of the diffusion plate 124 may enable a laminar flow of the gas-based etchant to be achieved in the processing chamber 102.

The body 126 of the diffusion plate 124 may be secured to the upper cover 106 of the processing chamber 102 by one or more support members 130. The support member(s) 130 may function as stand-offs that provide for space between the diffusion plate 124 and the upper cover 106 so that gas-based etchant can flow between the diffusion plate 124 and the upper cover 106. The support member(s) 130 may include threaded posts, screws, and/or another type of support member that can be removably attached to the upper cover 106 and to the body 126 of the diffusion plate 124.

As further shown in FIG. 1, the body 126 of the diffusion plate 124 may be curved between a center of the body 126 to a perimeter of the body 126. The body 126 may be curved upward in the processing chamber 102 such that the center of the body 126 is located closer to the chuck 114 than the perimeter of the body 126, and such that the perimeter of the body 126 is located closer to the upper cover 106 of the processing chamber than the center of the body 126. Thus, the body 126 has an arc-shaped cross-sectional profile that has a radius of curvature (dimension D1). The curvature of the body 126 of the diffusion plate 124 provides a greater volume in which gas-based etchant is permitted to flow between the diffusion plate 124 and the upper cover 106 near the center of the diffusion plate 124, and less volume in which gas-based etchant is permitted to flow between the diffusion plate 124 and the upper cover 106 near the perimeter of the diffusion plate 124. This promotes equalization of the flow rates of the gas-based etchant through the holes 128 in the body 126 across the diffusion plate 124.

The radius of curvature of the body 126 may be included in a range of approximately 8 times a radius of the diffusion plate 8 to approximately 24 times the radius of the diffusion plate 124. If the radius of curvature of the body 126 is less than approximately 8 times the radius of the diffusion plate 124, the body 126 may be too curved, which may result in interference between the perimeter of the body 126 and the upper cover 106. This may result in the diffusion plate 124 being unable to be secured to the upper cover 106. If the radius of curvature of the body 126 is greater than approximately 24 times the radius of the diffusion plate 124, the curvature of the body 126 may not be pronounced enough to impact the flow rate uniformity of the gas-based etchant. However, other values and ranges for the radius of curvature of the body 126 of the diffusion plate 124 are within the scope of the present disclosure.

As further shown in FIG. 1, the body 126 of the diffusion plate 124 may have a thickness (dimension D2). In some implementations, the thickness of the body 126 of the diffusion plate 124 is included in a range of approximately 1 millimeter to approximately 6 millimeters to provide sufficient structural rigidity for the diffusion plate 124. However, other values and ranges are included within the scope of the present disclosure.

As further shown in FIG. 1, the support member(s) 130 may have a length (dimension D3) between the body 126 of the diffusion plate 124 and the upper cover 106 of the processing chamber 102. In some implementations, the length of the support member(s) 130 is included in a range of approximately 3 millimeters to approximately 5 millimeters to provide a sufficient standoff distance between the diffusion plate 124 and the upper cover 106, and to accommodate the curvature of the body 126 of the diffusion plate 124. However, other values and ranges are within the scope of the present disclosure. In some implementations, the length of the support member(s) 130 is greater than a deflection between the center of the body 126 of the diffusion plate 124 and the perimeter of the body 126 of the diffusion plate 124.

As further shown in FIG. 1, the orientation of the curvature of the body 126 of the diffusion plate 124 in the processing chamber 102 results in a distance (dimension D4) between the approximate center of the diffusion plate 124 and the chuck 114 being greater than a distance (dimension D5) between the perimeter of the diffusion plate 124 and the chuck 114. Similarly, the orientation of the curvature of the body 126 of the diffusion plate 124 in the processing chamber 102 results in a distance (dimension D6) between the approximate center of the diffusion plate 124 and the upper cover 106 being greater than a distance (dimension D7) between the perimeter of the diffusion plate 124 and the upper cover 106. The length of the support member(s) 130 may be greater than the distance between the perimeter of the diffusion plate 124 and the upper cover 106 (e.g., D3>D7).

As further shown in FIG. 1, the semiconductor processing tool 100 may further include a controller 132. The controller 132 may be a processor, a combination of a processor and a memory, a system on chip (SoC), a programmable logic controller (PLC), an application-specific integrated circuit (ASIC), a field-programmable gate array (FPGA), a microcontroller, and/or another type of controller. The controller 132 may be communicatively coupled to one or more components of the semiconductor processing tool 100, such as the chuck 114, the pedestal 118, the RF source 120, and/or the heater element 122, among other examples. The controller 132 may be configured to control the operation of the semiconductor processing tool 100 by receiving signals from, and transmitting signals to, the component(s) of the semiconductor processing tool 100. The one or more signals may include a voltage, a current, a digital communication, and/or another type of signal. The controller 132 may communicate with the other component(s) of the semiconductor processing tool 100 over wired and/or wireless connections.

In some implementations, the controller 132 transmits one or more signals to the chuck 114 to cause the chuck 114 to apply a clamping force to secure a semiconductor substrate 116 to the chuck 114. In some implementations, the controller 132 transmits one or more signals to the pedestal 118 to cause the pedestal 118 to rotate the semiconductor substrate 116 on the chuck 114. In some implementations, the controller 132 transmits one or more signals to the RF source 120 to cause the RF source 120 to apply an RF bias to the chuck 114. In some implementations, the controller 132 transmits one or more signals to a gas delivery system (not shown) to cause the gas delivery system to provide a gas-based etchant into the processing chamber 102. In some implementations, the controller 132 transmits one or more signals to a vacuum pump (not shown) to cause the vacuum pump to generate a negative pressure in the processing chamber 102 so that gas-based etchant and etching byproducts are removed from the processing chamber 102 through the vent port(s) 112.

As indicated above, FIG. 1 is provided as an example. Other examples may differ from what is described with regard to FIG. 1.

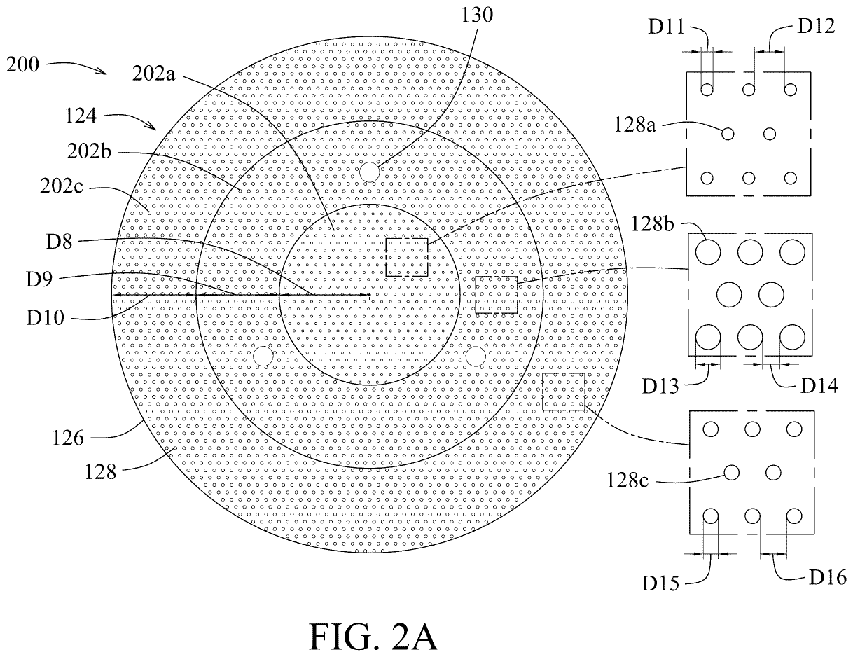

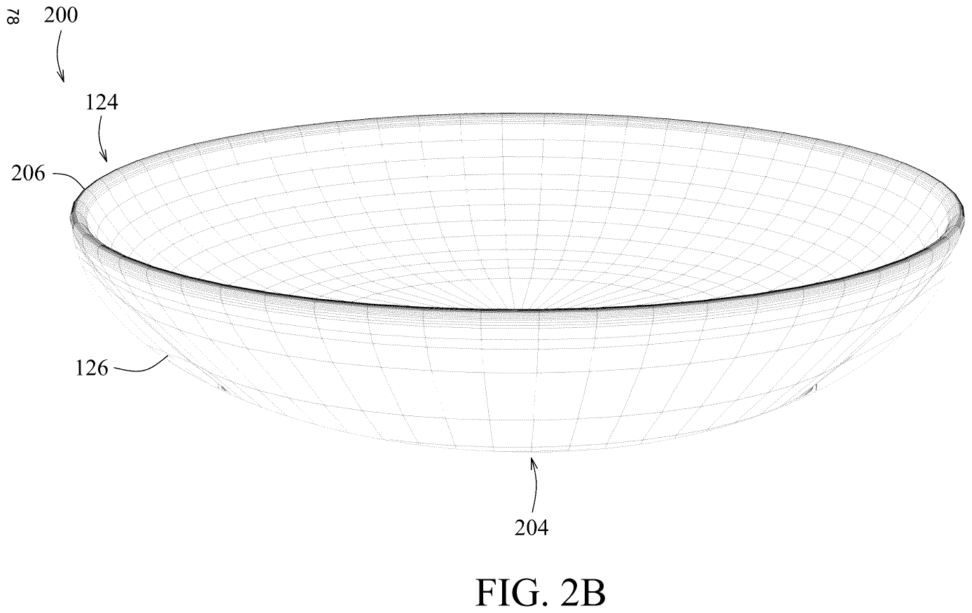

FIGS. 2A and 2B are diagrams of an example implementation 200 of a diffusion plate 124 described herein for use in the semiconductor processing tool 100 of FIG. 1. FIG. 2A illustrates a top view of the example implementation 200 of the diffusion plate 124. FIG. 2B illustrates a three-dimensional perspective view of the diffusion plate 124.

As shown in FIG. 2A, the body 126 of the diffusion plate 124 may have a substantially round or circular top view shape. The top view shape of the body 126 of the diffusion plate 124 may be similar to the top view shape of semiconductor substrates 116 that are to be processed by the semiconductor processing tool 100. The support member(s) 130 may be distributed across the body 126 of the diffusion plate 124 so that the diffusion plate 124 can be secured to the upper cover 106 of the processing chamber 102 of the semiconductor processing tool 100.

As further shown in FIG. 2A, the holes 128 through the body 126 of the diffusion plate 124 may be distributed across the body 126 of the diffusion plate 124 in the top view of the diffusion plate 124. The holes 128 may be arranged in a plurality of regions of the body 126 of the diffusion plate 124, and each region may have a different configuration of holes 128.

In the example implementation 200, the diffusion plate 124 includes a central region 202a, an annular region 202b around the central region 202a, and another annular region 202c around the annular region 202b. The central region 202a may be located at an approximate center of the body 126 of the diffusion plate 124, and the annular regions 202b and 202c may be located around the approximate center of the body 126 of the diffusion plate 124.

The central region 202a may have a radius (dimension D8) that corresponds to a first portion of the radius of the diffusion plate 124. The annular region 202b may have a radial thickness (dimension D9) that corresponds to a second portion of the radius of the diffusion plate 124. The annular region 202c may have a radial thickness (dimension D10) that corresponds to a third portion of the radius of the diffusion plate 124. The radius of the diffusion plate 124 may correspond to a combination of the radius of the central region 202a, the radial thickness of the annular region 202b, and the radial thickness of the annular region 202c (e.g., D8+D9+D10).

The radius of the diffusion plate 124 may be included in a range of approximately 100 millimeters to approximately 200 millimeters to provide sufficient gas flow coverage for 300 millimeter semiconductor substrates 116. If the radius of the diffusion plate is less than approximately 100 millimeters, the diffusion plate 124 may not provide sufficient gas flow coverage for 300 millimeter semiconductor substrates 116, resulting in reduced control over the gate flow rate of gas-based etchant at the perimeter of the semiconductor substrates 116. If the radius of the diffusion plate is greater than approximately 300 millimeters, the diffusion plate 124 may not fit in the processing chamber 102. However, other values and ranges for the radius of the diffusion plate 124 are within the scope of the present disclosure.

In some implementations, the radius of the central region 202a (dimension D8) is greater than 0% of the radius of the diffusion plate 124 to approximately 30% of the radius of the diffusion plate 124. However, other ranges and values are within the scope of the present disclosure. In some implementations, the radial width of the annular region 202b (dimension D9) is greater than 0% of the radius of the diffusion plate 124 to approximately 40% of the radius of the diffusion plate 124. However, other ranges and values are within the scope of the present disclosure. In some implementations, the radial width of the annular region 202c (dimension D10) is greater than 0% of the radius of the diffusion plate 124 to approximately 30% of the radius of the diffusion plate 124. However, other ranges and values are within the scope of the present disclosure.

In some implementations, the radius of the central region 202a, the radial thickness of the annular region 202b, and the radial thickness of the annular region 202c are approximately equal. For example, if the radius of the diffusion plate 124 is approximately 150 millimeters, the radius of the central region 202a, the radial thickness of the annular region 202b, and the radial thickness of the annular region 202 c may each be approximately 50 millimeters.

In some implementations, two or more of the radius of the central region 202a, the radial thickness of the annular region 202b, and/or the radial thickness of the annular region 202c are different values. For example, the radius of the central region 202a and the radial thickness of the annular region 202b may be different values, the radius of the central region 202a and the radial thickness of the annular region 202c may be different values, and/or the radial thickness of the annular region 202b and the radial thickness of the annular region 202c may be different values.

In some implementations, the radial thickness of the annular region 202b is greater than the radius of the central region 202a (e.g., D9>D8), and is greater than the radial thickness of the annular region 202c (e.g., D9>D10). Since the central region 202a is located under the gas inlet 110 of the processing chamber 102 of the semiconductor processing tool 100, the central region 202a may receive a high volume of gas-based etchant. The smaller size of the central region 202a helps to provide some amount of gas flow restriction for the gas-based etchant relative to the annular region 202b. This helps to equalize the flow rates of the gas-based etchant for the central region 202a and the annular region 202b.

Since the annular region 202c is located at the perimeter of the diffusion plate 124, the gas-based etchant may flow more easily through the annular region 202c because the annular region 202c is located closer to the vent port(s) 112 than the annular region 202b. The smaller size of the annular region 202c helps to provide some amount of gas flow restriction for the gas-based etchant in the annular region 202c, and this gas flow restriction helps to equalize the flow rates of the gas-based etchant for the annular region 202b and the annular region 202c.

The central region 202a may include a subset of the holes 128 corresponding to a plurality of holes 128a having a first size. The annular region 202b may include a subset of the holes 128 corresponding to a plurality of holes 128b having a second size. The annular region 202c may include a subset of the holes 128 corresponding to a plurality of holes 128c having a third size. The sizes of the holes 128a-128c may be selected so that the gas flow rate of gas-based etchant across the central region 202a, the annular region 202b, and the annular region 202c is substantially equalized as the gas-based etchant flows through the holes 128a-128c.

The first size, the second size, and the third size may each be different from each other to achieve gas flow equalization across the diffusion plate 124. For example, the size of the holes 128b in the annular region 202b may be greater than the size of the holes 128a in the central region 202a, and may be greater than the size of the holes 128c in the annular region 202c. The size of the holes 128c in the annular region 202c may be greater than the size of the holes 128a in the central region 202a. The sizes of the holes 128a and 128c being smaller than the size of the holes 128b provides gas flow restriction in the central region 202a and in the annular region 202c, which promotes equalization of the gas flow rates across the central region 202a, the annular region 202b, and the annular region 202c. In particular, the size of the holes 128a being smaller than the size of the holes 128b compensates for the high gas flow rate of gas-flow etchant directly under the gas inlet 110 in the processing chamber 102 by restricting the flow of the gas-based etchant in the central region 202a to equalize the gas flow rates between the central region 202a and the annular region 202b. Moreover, the size of the holes 128c being smaller than the size of the holes 128b compensates for the high gas flow rate of gas-flow etchant near the vent port(s) 112 in the processing chamber 102 by restricting the flow of the gas-based etchant in the annular region 202c to equalize the gas flow rates between the annular region 202c and the annular region 202b.

As shown in close-up views of the holes 128a, 128b, and 128c in FIG. 2A, the holes 128a, 128b, and 128c may each have an approximate circle top view shape. Thus, the holes 128a, 128b, and 128c may each have an approximate cylinder three-dimensional shape. The holes 128a in the central region 202a may have a size (dimension D11) corresponding to a diameter of the holes 128a. Alternatively, the size of the holes 128a may be defined by the top view circumference or the top view area of the holes 128b. In other implementations, the holes 128a may have another top view shape (e.g., an approximately square top view shape, an approximately oval top view shape), and the size of the holes 128a may correspond to a top view width or a top view area of the top view shape of the holes 128a. The holes 128a may be spaced apart by a distance (dimension D12). The spacing of the holes 128a may be uniform across the central region 202a, or the central region 202a may include different portions having different spacings between holes 128a.

The holes 128b in the annular region 202b may have a size (dimension D13) corresponding to a diameter of the holes 128b. Alternatively, the size of the holes 128b may be defined by the top view circumference or the top view area of the holes 128b. In other implementations, the holes 128b may have another top view shape (e.g., an approximately square top view shape, an approximately oval top view shape), and the size of the holes 128b may correspond to a top view width or a top view area of the top view shape of the holes 128b. The holes 128b may be spaced apart by a distance (dimension D14). The spacing of the holes 128b may be uniform across the annular region 202b, or the annular region 202b may include different portions having different spacings between holes 128b.

The holes 128c in the annular region 202c may have a size (dimension D15) corresponding to a diameter of the holes 128c. Alternatively, the size of the holes 128c may be defined by the top view circumference or the top view area of the holes 128c. In other implementations, the holes 128c may have another top view shape (e.g., an approximately square top view shape, an approximately oval top view shape), and the size of the holes 128c may correspond to a top view width or a top view area of the top view shape of the holes 128c. The holes 128c may be spaced apart by a distance (dimension D16). The spacing of the holes 128c may be uniform across the annular region 202c, or the annular region 202c may include different portions having different spacings between holes 128c.

As indicated above, the size of the holes 128b may be greater than the size of the holes 128a and the size of the holes 128c. Accordingly, the diameter of the holes 128b may be greater than the diameter of the holes 128a (e.g., D13>D11) and the diameter of the holes 128c (e.g., D13>D15). The diameter of the holes 128c may be greater than the diameter of the holes 128a (e.g., D15>D11). In some implementations, the diameters of the holes 128a, 128b, and 128c are each greater than approximately 1 millimeter. However, other values for the diameters for the holes 128a, 128b, and 128c are within the scope of the present disclosure.

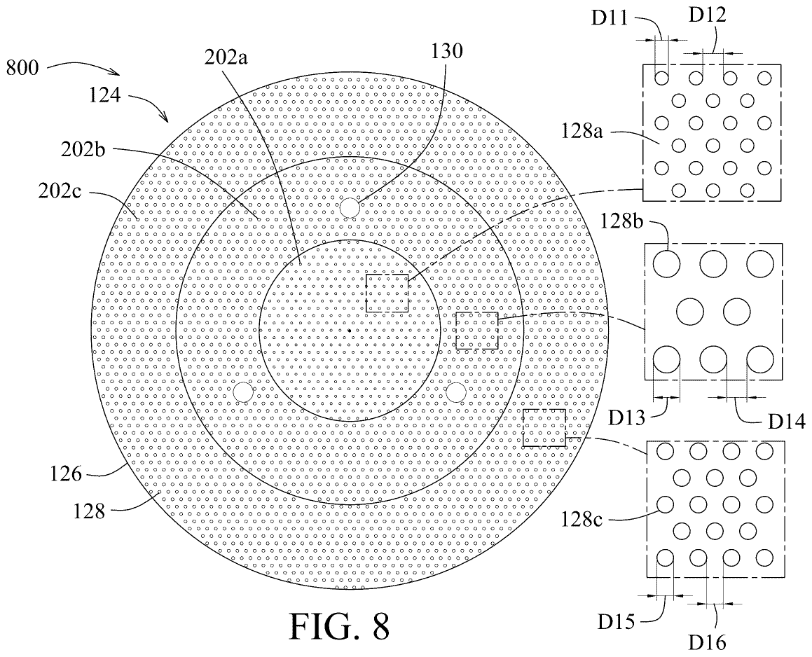

The spacing between the holes 128a in the central region 202a (dimension D12), the spacing between the holes 128b in the annular region 202b (dimension D14), and the spacing between holes 128c in the annular region 202c (dimension D16) may be different. For example, the spacing between the holes 128a in the central region 202a may be greater than the spacing between the holes 128b in the annular region 202b (e.g., D12>D14), the spacing between holes 128c in the annular region 202c may be greater than the spacing between the holes 128b in the annular region 202b (e.g., D16>D14), and the spacing between the holes 128a in the central region 202a may be greater than the spacing between the holes 128c in the annular region 202c (e.g., D12>D16). In this way, the density of holes 128a in the central region 202a, the density of holes 128b in the annular region 202b, and the density of holes 128c in the annular region 202c may be approximately equal. In other implementations (such as in an example implementation 800 of a diffusion plate 124 in FIG. 8), the density of holes 128a in the central region 202a and the density of holes 128b in the annular region 202b may be different densities, the density of holes 128a in the central region 202a and the density of holes 128c in the annular region 202c may be different densities, and/or the density of holes 128b in the annular region 202b and the density of holes 128c in the annular region 202c may be different densities to facilitate further tuning of the gas flow rates of gas-based etchant through the holes 128a in the central region 202a, through the holes 128b in the annular region 202b, and/or through the holes 128c in the annular region 202c.

As shown in FIG. 2B, the curvature of the body 126 of the diffusion plate 124 between center 204 of the body 126 and a perimeter 206 of the body 126 results in the diffusion plate 124 having a three-dimensional dome shape. The three-dimensional dome shape may be a hollow hemisphere, a hollow shell, a three-dimensional bowl shape, and/or another three-dimensional shape where the center 204 is located at an apex of the curve of the body 126, and the perimeter 206 of the body 126 corresponds to a rim of the three-dimensional shape.

As indicated above, FIGS. 2A and 2B are provided as an example. Other examples may differ from what is described with regard to FIGS. 2A and 2B.

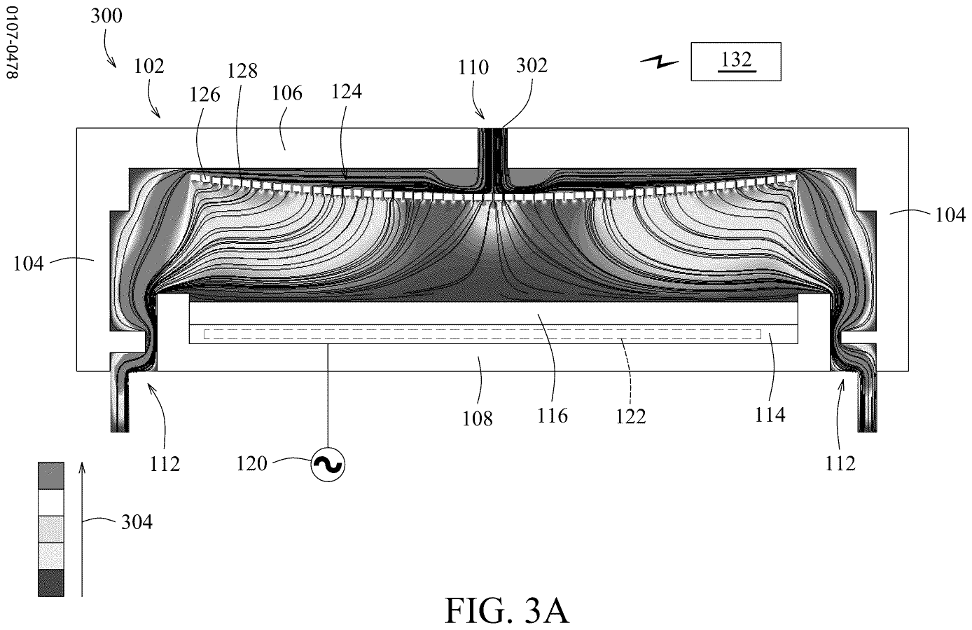

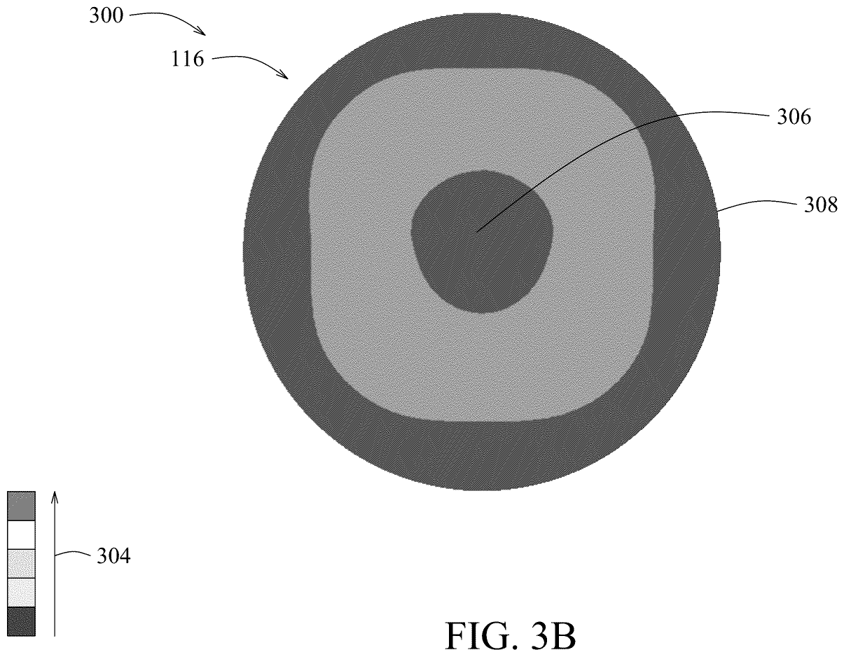

FIGS. 3A and 3B are diagrams of an example implementation 300 of an etch operation described herein. The etch operation may include a gas-based etch operation in which a gas-based etchant 302 is used to etch a layer and/or a structure on a semiconductor substrate 116 positioned in the processing chamber 102 of the semiconductor processing tool 100.

As shown in FIG. 3A, the semiconductor substrate 116 may be received in the processing chamber 102 of the semiconductor processing tool 100. A wafer transport tool (such as a robot arm) may retrieve the semiconductor substrate 116 from a transport carrier and may place the semiconductor substrate 116 on the chuck 114 in the processing chamber 102. The controller 132 may provide one or more signals to the chuck 114 to cause the chuck 114 to apply a clamping force to the semiconductor substrate 116 to secure the semiconductor substrate 116 to the chuck 114.

The controller 132 may provide one or more signals to a gas delivery system (not shown) of the semiconductor processing tool 100 to cause the gas delivery system to provide the gas-based etchant 302 into the processing chamber 102 through the gas inlet 110. The gas-based etchant 302 may include a fluorine-based gas, a chlorine-based gas, and/or another type of gas-based etchant.

The gas-based etchant 302 flows from the gas inlet 110 laterally along the top of the diffusion plate 124 between the diffusion plate 124 and the upper cover 106 of the processing chamber 102. The gas-based etchant 302 flows laterally outward from the center of the diffusion plate 124 toward the perimeter of the diffusion plate 124. Some of the gas-based etchant 302 flows outward past the perimeter of the diffusion plate 124 and along the sidewalls 104 of the processing chamber 102 toward the vent port(s) 112 at the bottom of the processing chamber 102.

As the gas-based etchant 302 flows laterally along the diffusion plate 124, some of the gas-based etchant 302 flows through the holes 128 through the body 126 of the diffusion plate 124, which modifies the flow path of the gas-based etchant 302. The curvature of the body 126 of the diffusion plate 124, and/or the different sizes of the holes 128a, 128b, and 128c in the central region 202a, the annular region 202b, and the annular region 202c, respectively, promotes a uniform gas flow rate 304 of the gas-based etchant 302 from the diffusion plate 124 toward the semiconductor substrate 116 on the chuck 114.

FIG. 3B illustrates a top view of the gas flow rate 304 of the gas-based etchant 302 across the semiconductor substrate 116 during the etch operation. As shown in FIG. 3B, the gas flow rate 304 of the gas-based etchant 302 between a center 306 of the semiconductor substrate 116 and a perimeter 308 of the semiconductor substrate 116 is substantially equalized because of the curvature of the body 126 of the diffusion plate 124, and/or because of the different sizes of the holes 128a, 128b, and 128c in the central region 202a, the annular region 202b, and the annular region 202c, respectively.

As indicated above, FIGS. 3A and 3B are provided as an example. Other examples may differ from what is described with regard to FIGS. 3A and 3B.

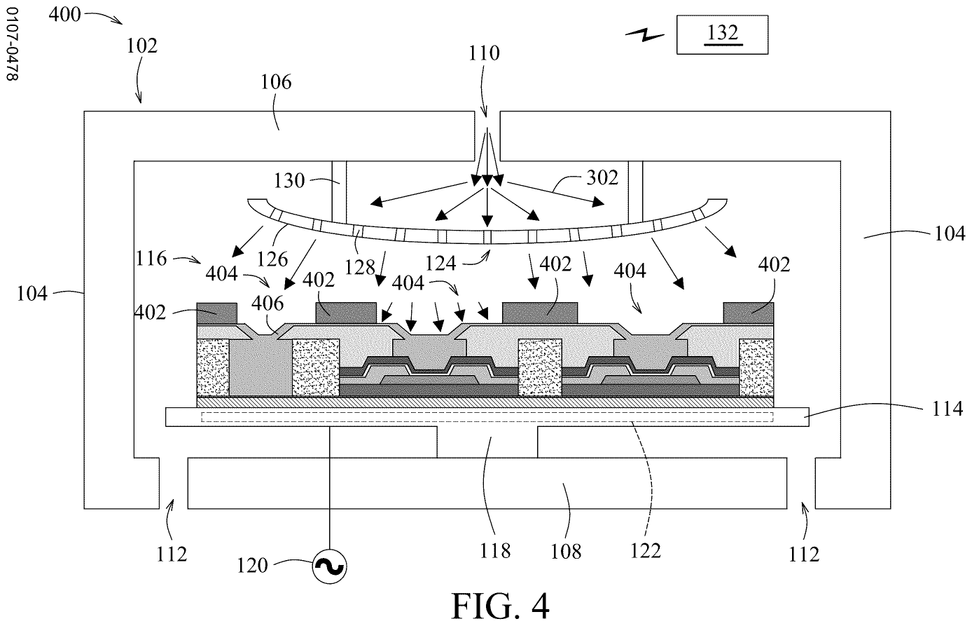

FIG. 4 is a diagram of an example implementation 400 of an etch operation described herein. The etch operation may include a gas-based etch operation in which a gas-based etchant 302 is used to etch a layer and/or a structure on a semiconductor substrate 116 positioned in the processing chamber 102 of the semiconductor processing tool 100. The semiconductor substrate 116 may include one or more semiconductor die packages, such as one or more integrated fanout dies. The integrated fanout dies may include one or more semiconductor dies, one or more redistribution structures, one or more redistribution layers (RDLs), and/or other structures and/or layers.

The gas-based etch operation performed in the example implementation 400 may be performed after a lithography operation to pattern a photoresist layer 402. The photoresist layer 402 may be patterned such that openings 404 are formed above via structures of the semiconductor substrate 116. The gas-based etch operation performed in the example implementation 400 may be performed to remove photoresist scum from the openings 404 so that the photoresist scum does not negatively affect a subsequent operation, such as attaching package connection structures to connection pads 406 in the openings 404. If the photoresist scum were not removed from the openings 404, the photoresist scum might otherwise act as a footing that prevents the package connection structures from adhering to connection pads 406.

As shown in FIG. 4, the semiconductor substrate 116 may be received in the processing chamber 102 of the semiconductor processing tool 100. A wafer transport tool (such as a robot arm) may retrieve the semiconductor substrate 116 from a transport carrier and may place the semiconductor substrate 116 on the chuck 114 in the processing chamber 102. The controller 132 may provide one or more signals to the chuck 114 to cause the chuck 114 to apply a clamping force to the semiconductor substrate 116 to secure the semiconductor substrate 116 to the chuck 114.

The controller 132 may provide one or more signals to a gas delivery system (not shown) of the semiconductor processing tool 100 to cause the gas delivery system to provide the gas-based etchant 302 into the processing chamber 102 through the gas inlet 110. The gas-based etchant 302 may include a fluorine-based gas, a chlorine-based gas, and/or another type of gas-based etchant.

The gas-based etchant 302 flows from the gas inlet 110 laterally along the top of the diffusion plate 124 between the diffusion plate 124 and the upper cover 106 of the processing chamber 102. The gas-based etchant 302 flows laterally outward from the center of the diffusion plate 124 toward the perimeter of the diffusion plate 124. Some of the gas-based etchant 302 flows outward past the perimeter of the diffusion plate 124 and along the sidewalls 104 of the processing chamber 102 toward the vent port(s) 112 at the bottom of the processing chamber 102.

As the gas-based etchant 302 flows laterally along the diffusion plate 124, some of the gas-based etchant 302 flows through the holes 128 through the body 126 of the diffusion plate 124, which modifies the flow path of the gas-based etchant 302. The curvature of the body 126 of the diffusion plate 124, and/or the different sizes of the holes 128a, 128b, and 128c in the central region 202a, the annular region 202b, and the annular region 202c, respectively, promotes a uniform gas flow rate 304 of the gas-based etchant 302 from the diffusion plate 124 toward the semiconductor substrate 116 on the chuck 114.

The gas-based etchant 302 may flow into the openings 404 across the semiconductor substrate 116 so that the photoresist scum is removed at a uniform rate across the semiconductor substrate 116, which reduces and/or minimizes the likelihood of photoresist scum remaining in the openings 404.

As indicated above, FIG. 4 is provided as an example. Other examples may differ from what is described with regard to FIG. 4.

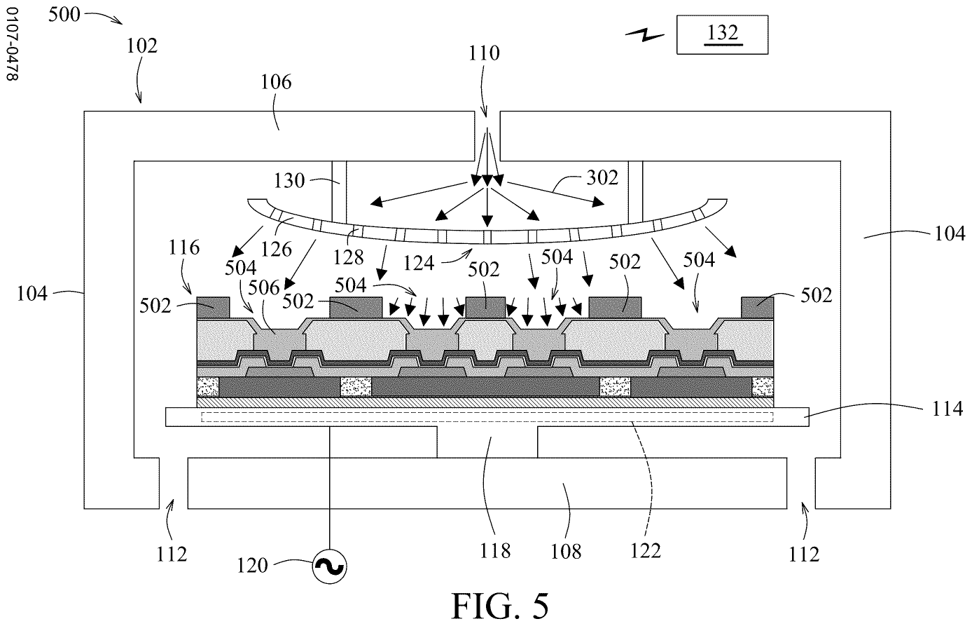

FIG. 5 is a diagram of an example implementation 500 of an etch operation described herein. The etch operation may include a gas-based etch operation in which a gas-based etchant 302 is used to etch a layer and/or a structure on a semiconductor substrate 116 positioned in the processing chamber 102 of the semiconductor processing tool 100. The semiconductor substrate 116 may include one or more semiconductor die packages, such as one or more chip on wafer on substrate dies. The integrated fanout dies may include one or more semiconductor dies that are positioned on a common package substrate, one or more redistribution structures, one or more RDLs, and/or other structure sand/or layers.

The gas-based etch operation performed in the example implementation 500 may be performed after a lithography operation to pattern a photoresist layer 502. The photoresist layer 502 may be patterned such that openings 504 are formed above via structures of the semiconductor substrate 116. The gas-based etch operation performed in the example implementation 500 may be performed to remove photoresist scum from the openings 504 so that the photoresist scum does not negatively affect a subsequent operation, such as attaching package connection structures to connection pads 506 in the openings 504. If the photoresist scum were not removed from the openings 504, the photoresist scum might otherwise act as a footing that prevents the package connection structures from adhering to connection pads 506.

As shown in FIG. 5, the semiconductor substrate 116 may be received in the processing chamber 102 of the semiconductor processing tool 100. A wafer transport tool (such as a robot arm) may retrieve the semiconductor substrate 116 from a transport carrier and may place the semiconductor substrate 116 on the chuck 114 in the processing chamber 102. The controller 132 may provide one or more signals to the chuck 114 to cause the chuck 114 to apply a clamping force to the semiconductor substrate 116 to secure the semiconductor substrate 116 to the chuck 114.

The controller 132 may provide one or more signals to a gas delivery system (not shown) of the semiconductor processing tool 100 to cause the gas delivery system to provide the gas-based etchant 302 into the processing chamber 102 through the gas inlet 110. The gas-based etchant 302 may include a fluorine-based gas, a chlorine-based gas, and/or another type of gas-based etchant.

The gas-based etchant 302 flows from the gas inlet 110 laterally along the top of the diffusion plate 124 between the diffusion plate 124 and the upper cover 106 of the processing chamber 102. The gas-based etchant 302 flows laterally outward from the center of the diffusion plate 124 toward the perimeter of the diffusion plate 124. Some of the gas-based etchant 302 flows outward past the perimeter of the diffusion plate 124 and along the sidewalls 104 of the processing chamber 102 toward the vent port(s) 112 at the bottom of the processing chamber 102.

As the gas-based etchant 302 flows laterally along the diffusion plate 124, some of the gas-based etchant 302 flows through the holes 128 through the body 126 of the diffusion plate 124, which modifies the flow path of the gas-based etchant 302. The curvature of the body 126 of the diffusion plate 124, and/or the different sizes of the holes 128a, 128b, and 128c in the central region 202a, the annular region 202b, and the annular region 202c, respectively, promotes a uniform gas flow rate 304 of the gas-based etchant 302 from the diffusion plate 124 toward the semiconductor substrate 116 on the chuck 114.

The gas-based etchant 302 may flow into the openings 504 across the semiconductor substrate 116 so that the photoresist scum is removed at a uniform rate across the semiconductor substrate 116, which reduces and/or minimizes the likelihood of photoresist scum remaining in the openings 504.

As indicated above, FIG. 5 is provided as an example. Other examples may differ from what is described with regard to FIG. 5.

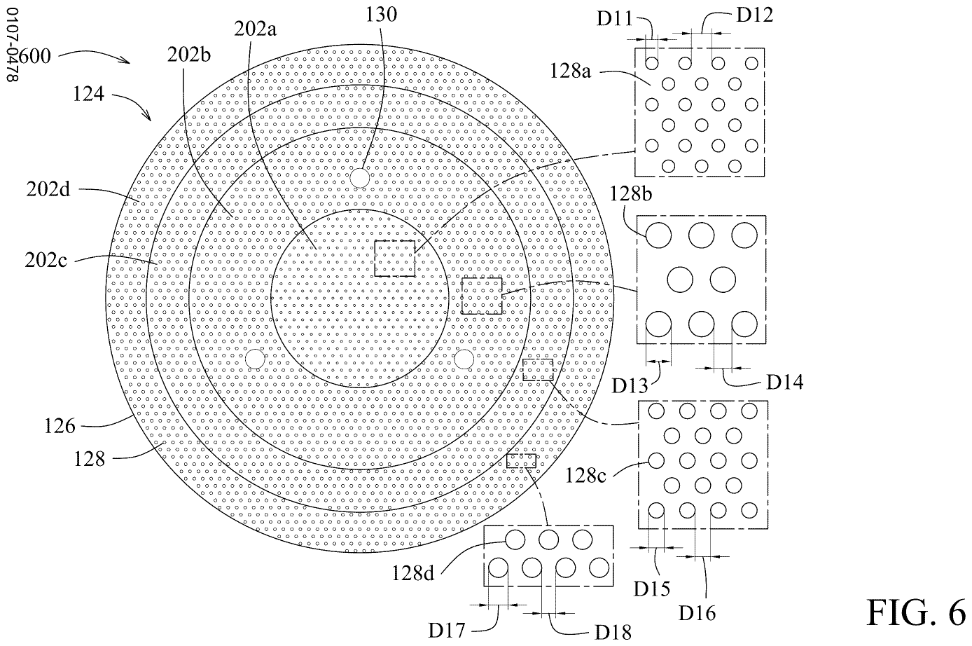

FIG. 6 is a diagram of an example implementation 600 of a diffusion plate 124 described herein for use in the semiconductor processing tool 100 of FIG. 1. As shown in FIG. 6, the example implementation 600 of the diffusion plate 124 is similar to the example implementation 200 of the diffusion plate 124 illustrated and described in connection with FIGS. 2A and 2B. However, the example implementation 600 of the diffusion plate 124 includes an additional annular region 202d around the annular region 202c. The annular region 202d may include holes 128d that have a size (dimension D17) and/or a spacing (dimension D18) that is different from the central region 202a, the annular region 202b, and/or the annular region 202c.

The additional region having different hole sizes and/or spacings facilitates further tuning of the gas flow rates of gas-based etchant through the holes 128a in the central region 202a, through the holes 128b in the annular region 202b, and/or through the holes 128c in the annular region 202c. The quantity of regions illustrated in FIGS. 2A, 6, 7, 8, and/or elsewhere herein are examples, and other quantities of regions of holes 128 of the diffusion plate 124 are within the scope of the present disclosure. The quantity of regions may be reduced in order to achieve a lower manufacturing complexity for the diffusion plate 124, or may be increased in order to achieve greater control over the gas flow of gas-based etchant.

As indicated above, FIG. 6 is provided as an example. Other examples may differ from what is described with regard to FIG. 6.

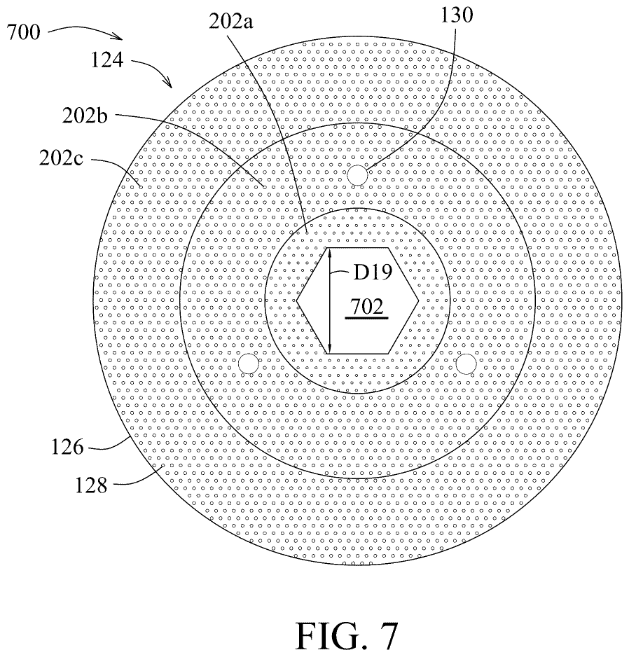

FIG. 7 is a diagram of an example implementation 700 of a diffusion plate 124 described herein for use in the semiconductor processing tool 100 of FIG. 1. As shown in FIG. 7, the example implementation 700 of the diffusion plate 124 is similar to the example implementation 200 of the diffusion plate 124 illustrated and described in connection with FIGS. 2A and 2B. However, the example implementation 700 of the diffusion plate 124 includes a blocked portion 702 in the central region 202a. The blocked portion 702 is a solid portion of the central region 202a that is free of holes 128a. The blocked portion 702 may be included in the central region 202a to further restrict the flow of gas-based etchant in the central region 202a for further tuning of the flow rate of the gas-based etchant across the diffusion plate 124.

As shown in FIG. 7, the blocked portion 702 of the central region 202a may have an approximately hexagonal top view shape. However, other top view shapes for the blocked portion 702 are within the scope of the present disclosure, such as an approximate circle top view shape, an asymmetric top view shape, and/or an amorphous top view shape, among other examples.

The blocked portion 702 may have a top view width (dimension D19) that is included in a range of approximately 20 millimeters to approximately 40 millimeters. However, other values and ranges for the top view width of the blocked portion 702 are within the scope of the present disclosure. In some implementations, the top view width of the blocked portion 702 is included in a range of approximately 40% the top view area of the central region 202 a to approximately 100% of the top view area of the central region 202 a.

As indicated above, FIG. 7 is provided as an example. Other examples may differ from what is described with regard to FIG. 7.

FIG. 8 is a diagram of an example implementation 800 of a diffusion plate 124 described herein for use in the semiconductor processing tool 100 of FIG. 1. As shown in FIG. 8, the example implementation 800 of the diffusion plate 124 is similar to the example implementation 200 of the diffusion plate 124 illustrated and described in connection with FIGS. 2A and 2B. However, in the example implementation 800 of the diffusion plate 124, the distance between holes 128a (dimension D12) in the central region 202a, the distance between holes 128b (dimension D14) in the annular region 202b, and the distance between the holes 128c (dimension D16) in the annular region 202c are approximately equal. Because of the differences in the sizes of the holes 128a, 128b, and 128c, this results in the density of holes 128a in the central region 202a and the density of holes 128b in the annular region 202b being different densities, the density of holes 128a in the central region 202a and the density of holes 128c in the annular region 202c being different densities, and/or the density of holes 128b in the annular region 202b and the density of holes 128c in the annular region 202c being different densities to facilitate further tuning of the gas flow rates of gas-based etchant through the holes 128a in the central region 202a, through the holes 128b in the annular region 202b, and/or through the holes 128c in the annular region 202c.

As indicated above, FIG. 8 is provided as an example. Other examples may differ from what is described with regard to FIG. 8.

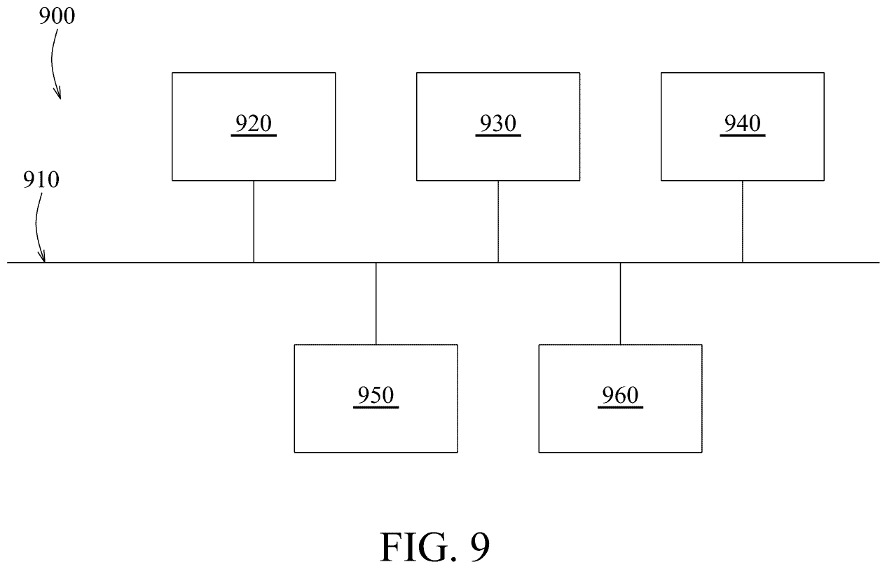

FIG. 9 is a diagram of example components of one or more devices 900 of FIG. 1 described herein. The device 900 may correspond to the controller 132. In some implementations, the controller 132 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

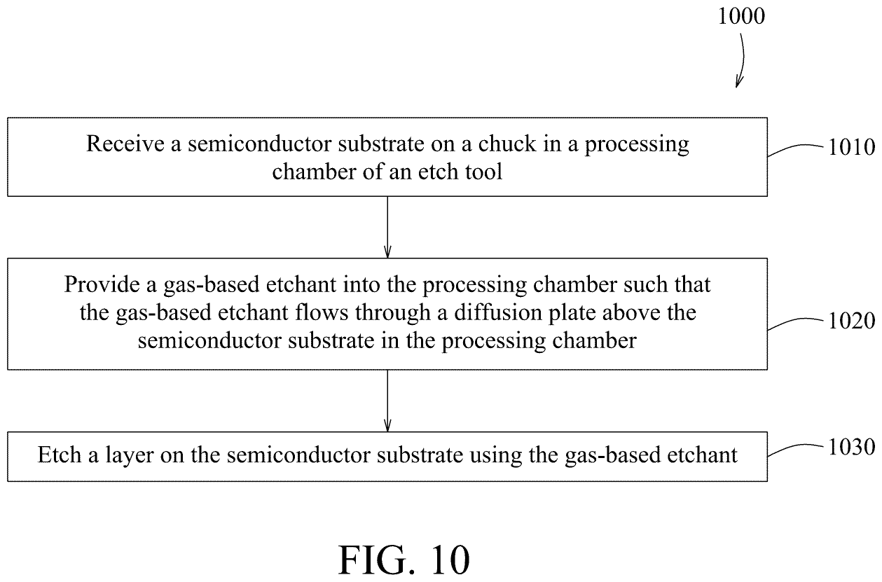

FIG. 10 is a flowchart of an example process 1000 associated with performing an etch operation. In some implementations, one or more process blocks of FIG. 10 are performed using an etch tool (e.g., the semiconductor processing tool 100). In some implementations, one or more process blocks of FIG. 10 are performed using another device or a group of devices separate from or including the semiconductor processing tool, such as a controller (e.g., the controller 132). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include receiving a semiconductor substrate on a chuck in a processing chamber of an etch tool (block 1010). For example, the semiconductor processing tool 100 may be used to receive a semiconductor substrate 116 on a chuck 114 in a processing chamber 102 of the semiconductor processing tool 100, as described herein.

As further shown in FIG. 10, process 1000 may include providing a gas-based etchant into the processing chamber such that the gas-based etchant flows through a diffusion plate above the semiconductor substrate in the processing chamber, wherein the diffusion plate has a body that has a dome shape (block 1020). For example, the semiconductor processing tool 100 may be used to provide a gas-based etchant 302 into the processing chamber 102 such that the gas-based etchant 302 flows through a diffusion plate 124 above the semiconductor substrate 116 in the processing chamber 102, as described herein. In some implementations, the diffusion plate 124 has a body 126 that has a dome shape.

As further shown in FIG. 10, process 1000 may include etching a layer on the semiconductor substrate using the gas-based etchant (block 1030). For example, the semiconductor processing tool 100 may be used to etch a layer on the semiconductor substrate 116 using the gas-based etchant 302, as described above.

Process 1000 may include additional implementations, such as any single implementation or any combination of implementations described below and/or in connection with one or more other processes described elsewhere herein.

In a first implementation, the gas-based etchant 302 flows through a first plurality of holes 128a in a central region 202a of the diffusion plate 124, and the gas-based etchant 302 flows through a second plurality of holes (e.g., holes 128b, holes 128c) in an annular region (e.g., an annular region 202b, an annular region 202c) of the diffusion plate 124 around the central region 202a, and a first width (e.g., a dimension D11) of a first hole 128a of the first plurality of holes 128a, and a second width (e.g., a dimension D13, a dimension D15) of a second hole of the second plurality of holes, are different widths.

In a second implementation, alone or in combination with the first implementation, the second width is greater than the first width.

In a third implementation, alone or in combination with one or more of the first and second implementations, a radial thickness (e.g., a dimension D9) of the annular region and a radius (e.g., a dimension D10) of the central region 202a are different.

In a fourth implementation, alone or in combination with one or more of the first through third implementations, the dome shape promotes uniformity between a first flow rate of the gas-based etchant 302 at an edge (e.g., a perimeter 308) of the semiconductor substrate 116 and a second flow rate of the gas-based etchant at a center 306 of the semiconductor substrate 116.

In a fifth implementation, alone or in combination with one or more of the first through fourth implementations, a radius of curvature (e.g., a dimension D1) of the dome shape of the diffusion plate 124 is included in a range of approximately 8 times a radius of the diffusion plate 124 to approximately 24 times the radius of the diffusion plate 124.

In a sixth implementation, alone or in combination with one or more of the first through fifth implementations, a distance (e.g., a dimension D5) between a perimeter of the diffusion plate 124 and the chuck 114 is greater than a distance (e.g., a dimension D4) between a center of the diffusion plate 124 and the chuck 114.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, an etch tool (e.g., a gas-based etch tool) may be fitted with a diffusion plate that is included in the etch tool to promote a uniform flow rate of a gas-based etchant across a semiconductor substrate in a gas-based etch operation. The diffusion plate may have a curved three-dimensional shape, such as a bowl shape, a dome shape, and/or another type of hollow shell shape. The upward curvature of the diffusion plate may equalize the gate flow rate of the gas-based etchant across a semiconductor substrate by restricting the flow of the gas-based etchant as the gas-based etchant flows toward the perimeter of the diffusion plate. Additionally and/or alternatively, the diffusion plate includes a plurality of holes through which the gas-based etchant flows, and the holes may be arranged in regions of the diffusion plate having different sized holes. The hole sizes in the different regions are configured to equalize the gate flow rate of the gas-based etchant across a semiconductor substrate. In this way, the high uniformity in the flow rate of the gas-based etchant enables a high uniformity in the etch rate across the semiconductor substrate to be achieved. The high uniformity in the etch rate across the semiconductor substrate reduces the likelihood and/or the rate of defect formation in semiconductor devices formed on the semiconductor substrate by reducing over-etching and under-etching across the semiconductor substrate.

As described in greater detail above, some implementations described herein provide a method. The method includes receiving a semiconductor substrate on a chuck in a processing chamber of an etch tool. The method includes providing a gas-based etchant into the processing chamber such that the gas-based etchant flows through a diffusion plate above the semiconductor substrate in the processing chamber, where the diffusion plate has a body that has a dome shape. The method includes etching a layer on the semiconductor substrate using the gas-based etchant.

As described in greater detail above, some implementations described herein provide a diffusion plate. The diffusion plate includes a body. The diffusion plate includes a first plurality of holes through a central region of the body. The diffusion plate includes a second plurality of holes through a first annular region of the body that surrounds the central region. The diffusion plate includes a third plurality of holes through a second annular region of the body that surrounds the first annular region, where a first size of a first hole of the first plurality of holes, a second size of a second hole of the second plurality of holes, and a third size of a third hole of the third plurality of holes are different sizes.

As described in greater detail above, some implementations described herein provide a semiconductor processing tool. The semiconductor processing tool includes a processing chamber comprising sidewalls, an upper cover, and a chamber floor that define an internal area of the processing chamber. The semiconductor processing tool includes a chuck within the internal area and located adjacent to the chamber floor. The semiconductor processing tool includes vent ports in the chamber floor under the chuck. The semiconductor processing tool includes a diffusion plate within the internal area. The diffusion plate is located above the chuck and adjacent to the upper cover. The diffusion plate includes a body, where a central region of the body is located further away from the upper cover than from a perimeter of the body a plurality of holes through the body. The semiconductor processing tool includes a gas inlet in the upper cover above the diffusion plate.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a semiconductor substrate on a chuck in a processing chamber of an etch tool;
providing a gas-based etchant into the processing chamber such that the gas-based etchant flows through a diffusion plate above the semiconductor substrate in the processing chamber,
wherein the diffusion plate has a body that has a dome shape; and
etching a layer on the semiconductor substrate using the gas-based etchant.

2. The method of claim 1, wherein the gas-based etchant flows through a first plurality of holes in a central region of the diffusion plate; and
wherein the gas-based etchant flows through a second plurality of holes in an annular region of the diffusion plate around the central region; and
wherein a first width of a first hole of the first plurality of holes, and a second width of a second hole of the second plurality of holes, are different widths.

3. The method of claim 2, wherein the second width is greater than the first width.

4. The method of claim 2, wherein a radial thickness of the annular region and a radius of the central region are different.

5. The method of claim 1, wherein the dome shape promotes uniformity between a first flow rate of the gas-based etchant at an edge of the semiconductor substrate and a second flow rate of the gas-based etchant at a center of the semiconductor substrate.

6. The method of claim 1, wherein a radius of curvature of the dome shape of the diffusion plate is included in a range of approximately 8 times a radius of the diffusion plate to approximately 24 times the radius of the diffusion plate.

7. The method of claim 1, wherein a distance between a perimeter of the diffusion plate and the chuck is greater than a distance between a center of the diffusion plate and the chuck.

8. A diffusion plate, comprising:
a body;
a first plurality of holes through a central region of the body;
a second plurality of holes through a first annular region of the body that surrounds the central region; and
a third plurality of holes through a second annular region of the body that surrounds the first annular region,
wherein a first size of a first hole of the first plurality of holes, a second size of a second hole of the second plurality of holes, and a third size of a third hole of the third plurality of holes are different sizes.

9. The diffusion plate of claim 8, wherein the second size of the second hole is greater than the first size of the first hole.

10. The diffusion plate of claim 9, wherein the second size of the second hole is greater than the third size of the third hole.

11. The diffusion plate of claim 10, wherein the third size of the third hole is greater than the first size of the first hole.

12. The diffusion plate of claim 8, wherein a first density of the first plurality of holes in the central region, a second density of the second plurality of holes in the first annular region, and a third density of the third plurality of holes in the second annular region are approximately a same density.

13. The diffusion plate of claim 8, wherein a first density of the first plurality of holes in the central region, and a second density of the second plurality of holes in the first annular region, are different densities.

14. The diffusion plate of claim 13, wherein a third density of the third plurality of holes in the second annular region, and the second density of the second plurality of holes in the first annular region, are different densities; and
wherein the third density of the third plurality of holes in the second annular region, and the first density of the first plurality of holes in the central region, are different densities.

15. A semiconductor processing tool, comprising:
a processing chamber comprising sidewalls, an upper cover, and a chamber floor that define an internal area of the processing chamber;
a chuck within the internal area and located adjacent to the chamber floor;
vent ports in the chamber floor under the chuck;
a diffusion plate within the internal area,
wherein the diffusion plate is located above the chuck and adjacent to the upper cover,
wherein the diffusion plate comprises:
a body,
wherein a central region of the body is located further away from the upper cover than from a perimeter of the body; and
a plurality of holes through the body; and
a gas inlet in the upper cover above the diffusion plate.

16. The semiconductor processing tool of claim 15, wherein the diffusion plate further comprises:
a plurality of support members attached to the body,
wherein the plurality of support members secure the diffusion plate to the upper cover of the processing chamber, and
wherein lengths of the plurality of support members are greater than a distance between the perimeter of the body of the diffusion plate and the upper cover of the processing chamber.

17. The semiconductor processing tool of claim 15, wherein a distance between the perimeter of the body of the diffusion plate and the chuck is greater than a distance between the central region of the diffusion plate and the chuck.

18. The semiconductor processing tool of claim 15, wherein two or more of the plurality of holes have different diameters.

19. The semiconductor processing tool of claim 15, wherein a first subset of the plurality of holes are located in a central region of the body;
wherein a second subset of the plurality of holes are located in a first annular region of the body;
wherein a third subset of the plurality of holes are located in a second annular region of the body;
wherein first sizes of the first subset of the plurality of holes are less than second sizes of the second subset of the plurality of holes; and
wherein third sizes of the third subset of the plurality of holes are less than the second sizes of the second subset of the plurality of holes.

20. The semiconductor processing tool of claim 19, wherein the first annular region is located around the central region; and
wherein the second annular region is located around the first annular region.
